(19) United States
(12) Patent Application Publication
(10) Pub. No.: US 2002/0017738 A1
(43) Pub. Date: Feb. 14, 2002

(54) Resin sealing method and resin sealing apparatus

(75) Inventor: Fumio Miyajima, Nagano (JP)

Correspondence Address: SUGHRUE, MION, ZINN, MACPEAK & SEAS, PLLC, 2100 Pennsylvania Avenue, N.W., Washington, DC, 20037, US

(73) Assignee: APIC YAMADA CORPORATION

(21) Appl. No.: 09/884,054

(22) Filed: Jun. 20, 2001

(30) Foreign Application Priority Data
Jun. 20, 2000 (JP) P. 2000-185328

(51) Int. Cl. B29C 45/14; H01L 21/56

(52) U.S. Cl. 264/272.17; 264/316

(57) ABSTRACT

Under-fill molding is carried out by preferentially sending a sealing resin 22 under pressure into a clearance portion 21 between a semiconductor chip 6 and a substrate 2, and a molded component gate runner 25 that is connected to the under-fill portion 24 is separated at the substrate end position.

### BACKGROUND OF THE INVENTION

1. Field of the invention

The present invention relates to a resin sealing method and a resin sealing apparatus for sealing resin by delivering a sealing resin into a cavity including clearance between a semiconductor chip and a substrate under pressure in a state where a molded component, in which the semiconductor chip is connected to the substrate by flip chip bonding, is clamped by a metallic molding die.

2. Description of the Related Art

So-called under-fill molding is carried out in order to relieve influence due to thermal stress between a semiconductor chip and a substrate after the corresponding semiconductor chip is connected to a substrate by flip-chip bonding. The under-fill molding is such that liquid-like resin is dripped to the surrounding equivalent to one or two sides of a semiconductor chip by potting, and resin is poured between the semiconductor chip and substrate by a capillary phenomenon by inclining the substrate, wherein the resin is heated and hardened to seal resin therein.

Also, air bubbles are likely to occur in the liquid-like resin since the clearance between the semiconductor chip and substrate is narrowed. Therefore, the present applicant proposed a resin sealing method and a resin sealing apparatus (Japanese Unexamined Patent Publication No. Hei-11-274197) in which under-fill molding is carried out by a transfer molding method instead of the potting method due to in sufficient fluidity since the resin includes fillers, etc., and inferior production efficiency.

In the present method, a substrate (a component to be molded) to which a semiconductor chip is connected by flip chip bonding is set in a lower mold, a release film that covers the upper surface of the substrate and a resin pass is adsorbed onto the surfaces of the upper and lower molds, and resin tablets are inputted in a pot. Then, the component to be molded is clamped by closing a metallic molding die, and the resin tablets are delivered under pressure by a plunger to seal the substrate with resin while heating and melting the resin tablets. In this case, in order to securely carry out under-fill molding in the clearance between the semiconductor chip and a substrate, side blocks are provided at both side faces (both sides with respect to the resin inputting direction to the under-fill portion) of the semiconductor chip, and the side blocks are caused to protrude in advance in a cavity recess portion, and the release film is pushed onto the substrate, wherein under-fill molding is carried out. By retreating the side blocks when the resin flows out from the downstream side of the semiconductor chip, the remaining sides of the semiconductor chip are sealed with resin.

In the resin sealing method and resin sealing apparatus, which are disclosed by Japanese Unexamined Patent Publication No. Hei-11-274197, a molded component separated from a metallic molding die, which is put between the upper and lower release films, is made integral with a gate runner of the molded component, which is not necessary, the gate runner of the molded component must be broken off, which is removed on the metallic molding die or after it is taken out from the metallic molding die.

However, if the gate rubber is broken off on the metallic molding die, a problem remains in how the molded component (package) is separated from unnecessary resin in a state where it is covered by the upper and lower release films, wherein if the resin sealing apparatus is automated, there is a possibility that the detaching mechanism of molded components will be complicated. Also, if the gate rubber is broken off after the molded component is taken out from the metallic molding die, the molded component may be likely to be deflected because the molded component is integral with its gate runner when transferring the molded component together with the release films, wherein the molded component may be likely to be broken, and there is another problem in that unnecessary resin is broken on the way of the gate runner and is dropped.

### SUMMARY OF THE INVENTION

It is therefore an object of the invention to solve the problems and shortcomings in the prior arts and to provide a resin sealing method and resin sealing apparatus by which under-fill molding of packages mounted in the form of flip-chip can be uniformly carried out, the production cost and running cost thereof can be decreased, and the gate runner can be easily broken off at a fixed position after the molding.

In order to solve the above problems and shortcomings, the present invention is provided with the following construction.

That is, the resin sealing method comprises the steps of: carrying the molded component in the metallic molding die, covering the upper mold face including a cavity recess portion, in which the semiconductor chip is accommodated, and a resin pass that communicates with the cavity recess portion, with a release film, and clamping the molded component by an upper mold and a lower mold; and delivering under pressure a sealing resin to a clearance portion between the semiconductor chip and substrate with priority, performing under-fill molding, and separating a molded component gate runner, which is connected to the under-fill portion, at the substrate end position.

Also, the resin sealing method is featured in that a movable block secured in the upper mold is caused in advance to protrude into a cavity recess portion at both side faces of the semiconductor chip, under-fill molding is performed with the release film pushed and connected to the substrate, and both side faces of the semiconductor chip are sealed with resin by retreating the movable block.

Further, the resin sealing method is featured in that resin is sealed so that the resin molding thickness of the portion that communicates from the substrate end of the molded component gate runner to the under-fill portion is made thinner at the pot side than that at the substrate end.

In addition, the resin sealing method is featured in that resin is sealed so that a V-shaped groove is formed at the substrate end position of a molded component gate runner remaining on the substrate.

And, the resin sealing method is featured in that a movable gate pin is provided at the substrate end position of the upper mold so as to protrude with respect a resin pass, and by closing the resin pass by the movable gate pin after the under-fill molding is completed, resin is sealed by pushing a sealing resin at the substrate end position back to the pot side.

Also, the resin sealing method is featured in that a movable runner block is provided in the upper mold so as to protrude from the substrate end to the resin pass that communicates with the cavity recess portion, and by closing the resin pass by the movable runner block after the under-fill molding is completed, resin is sealed by pushing the sealing resin on the substrate back to the pot side.

Still further, a resin sealing apparatus comprises: the metallic molding die including a lower mold on which the molded component is placed, a cavity recess portion in which the semiconductor chip is accommodated, and an upper mold in which a resin pass that communicates with the cavity recess portion is formed; and a release film that covers the cavity recess portion of the upper mold and the resin pass that communicates with the cavity recess portion; wherein a sealing resin is delivered under pressure to a clearance portion between the semiconductor chip and substrate with priority, performing under-fill molding, and the semiconductor chip is sealed with resin with a molded component gate runner to be connected to the under-fill portion remaining on the substrate.

Also, the resin sealing apparatus is featured in that a movable block is provided at both side faces of the semiconductor chip in the upper mold so as to protrude into the cavity recess portion, the movable block is caused to protrude in advance into the cavity recess portion, under-fill molding is performed with the release film pushed to the substrate, and both side faces of the semiconductor chip are sealed with resin after retreating the movable block.

In addition, the resin sealing apparatus is featured in that the cross section of a resin pass at a portion that communicates from the substrate end of the metallic die gate runner formed on the upper mold to the cavity recess portion is formed to be smaller than the cross section of the resin pass at a portion that communicates from the substrate end to a pot.

Further, the resin sealing apparatus is featured in that a chamfered portion is formed at the upper edge portion including at least respective corners of the semiconductor chip.

Also, the resin sealing apparatus is featured in that a movable gate pin is provided at the substrate end position of the upper mold so as to protrude with respect to the resin pass, and the semiconductor chip is sealed with resin by pushing a sealing resin at the substrate end position back to the pot side by closing the resin pass by the movable gate pin after the under-fill molding is completed.

Further, the resin sealing apparatus is featured in that a movable runner block is provided in the upper mold so as to protrude from the substrate end to the resin pass that communicates with the cavity recess portion, and by closing the resin pass by the movable runner block after the under-fill molding is completed, resin is sealed by pushing the sealing resin on the substrate back to the pot side.

### BRIEF DESCRIPTION OF THE DRAWINGS

FIGS. 1A to 1C are, respectively, an exemplary upper view of a metallic molding die of a resin sealing apparatus, a cross-sectional view taken along the arrows A-A, and a cross-sectional view taken along the arrows B-B, which shows states before and after resin is sealed.

FIGS. 2A to 2C are, respectively, a perspective view of a molded component after resin is sealed, a view taken from the above, and a cross-sectional view taken along the arrows C-C.

FIGS. 3A to 3E are, respectively, a perspective view of a molded component, after resin is sealed, according to another embodiment, an upper view, a cross-sectional view taken along the arrows C-C, a cross-sectional view taken along the arrows D-D, and an explanatory view of the shape of a semiconductor chip.

FIGS. 4A to 4C are, respectively, explanatory views showing the shape of a movable block.

FIGS. 5A to 5C are, respectively, exemplary upper views of a metallic molding die of a resin sealing apparatus showing another example, and cross-sectional views taken along the arrows A-A, and cross-sectional views taken along the arrows B-B, which show states before and after resin is sealed.

FIGS. 6A to 6C are, respectively, exemplary upper views of a metallic molding die of a resin sealing apparatus showing another example, and cross-sectional views taken along the arrows A-A, and cross-sectional views taken along the arrows B-B, which show states before and after resin is sealed,

FIGS. 7A to 7C are, respectively, exemplary upper views of a metallic molding die of a resin sealing apparatus showing another example, cross-sectional views taken along the arrows, and cross-sectional views taken along the arrows A-A, and cross-sectional views taken along the arrows B-B, which show states before and after resin is sealed,

FIGS. 8A and 8B are, respectively, an explanatory sectional view of the metallic molding die of FIG. 7A, and a partially enlarged view thereof.

FIGS. 9A to 9C are a perspective view of a molded component after resin sealing is completed in FIG. 7A, an upper view there of, and a cross-sectional view taken along the arrows C-C.

### DETAILED DESCRIPTION OF THE PRESENT INVENTION

Hereinafter, a detailed description is given of preferred embodiments of the resin sealing method and resin sealing apparatus according to the invention with reference to the accompanying drawings.

First Embodiment

First, a description is given of a resin sealing method and resin sealing apparatus for sealing a component to be molded (substrate), in which a semiconductor chip is connected to a substrate in the form of flip chip, with resin by transfer molding.

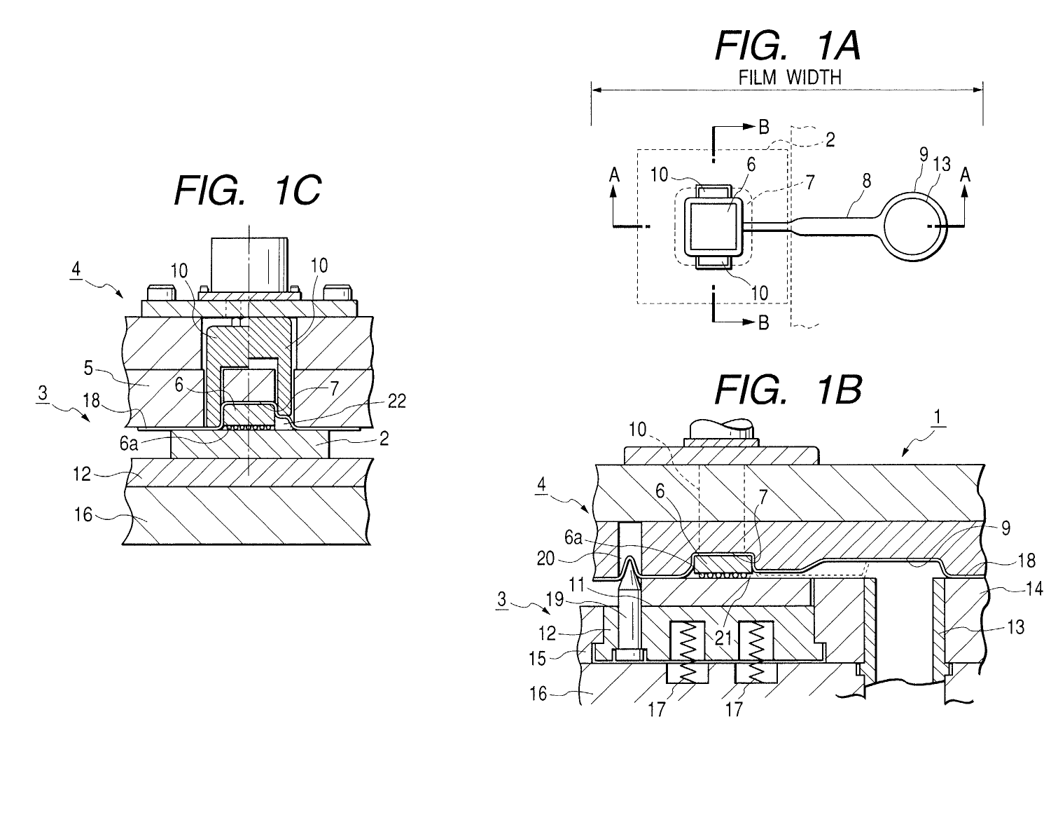

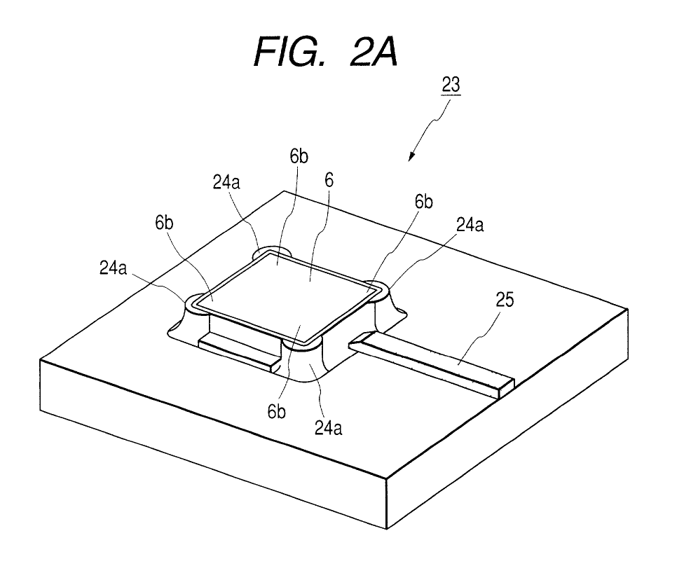

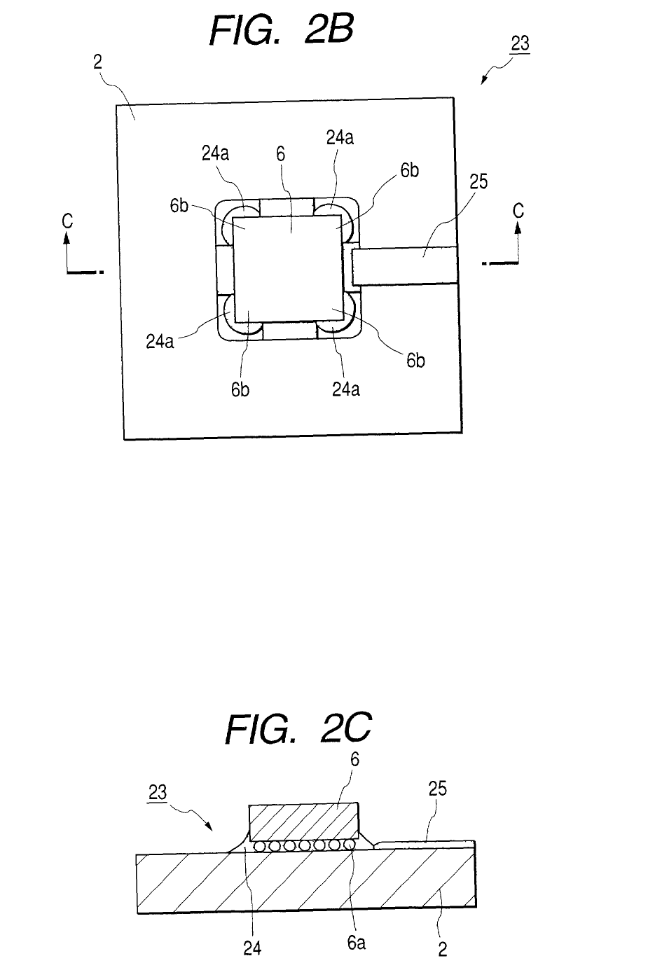

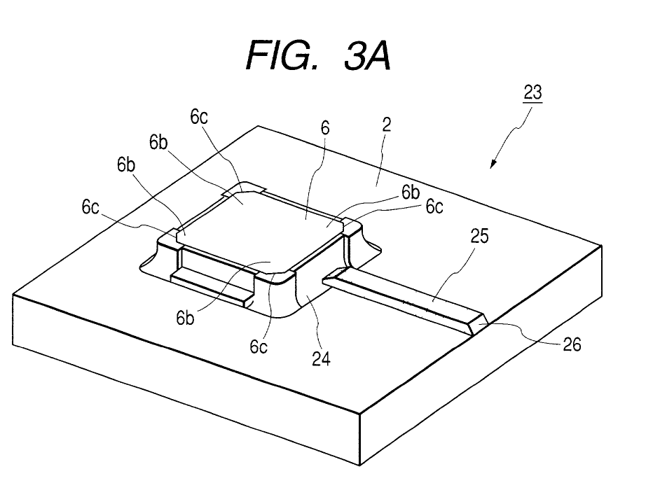

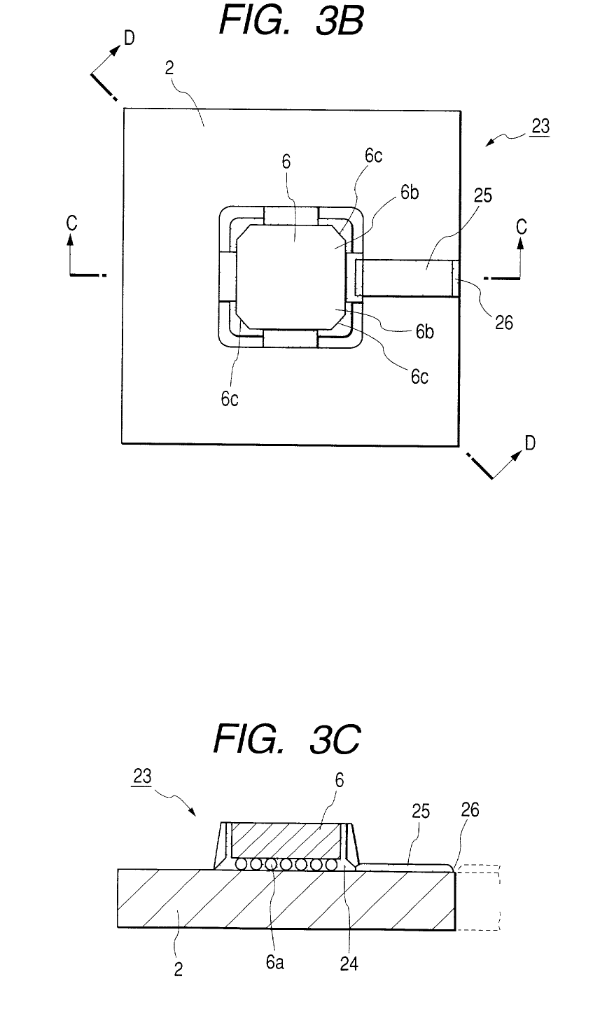

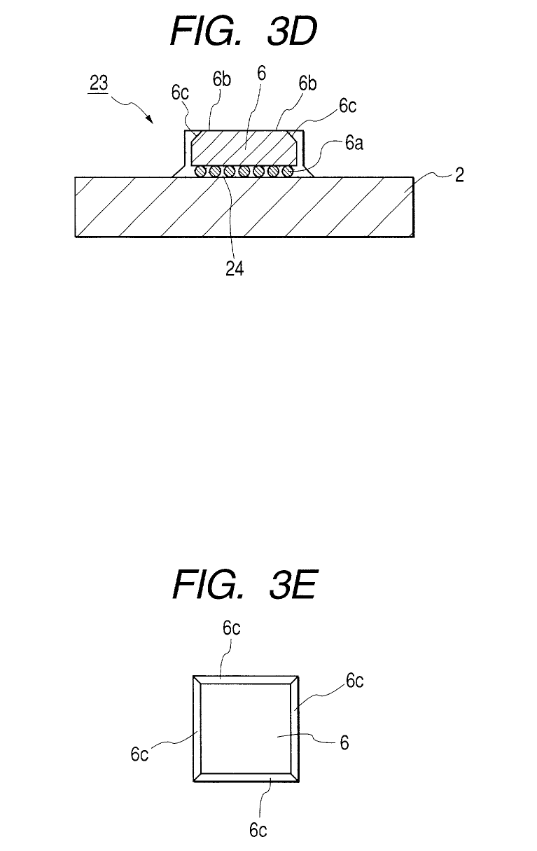

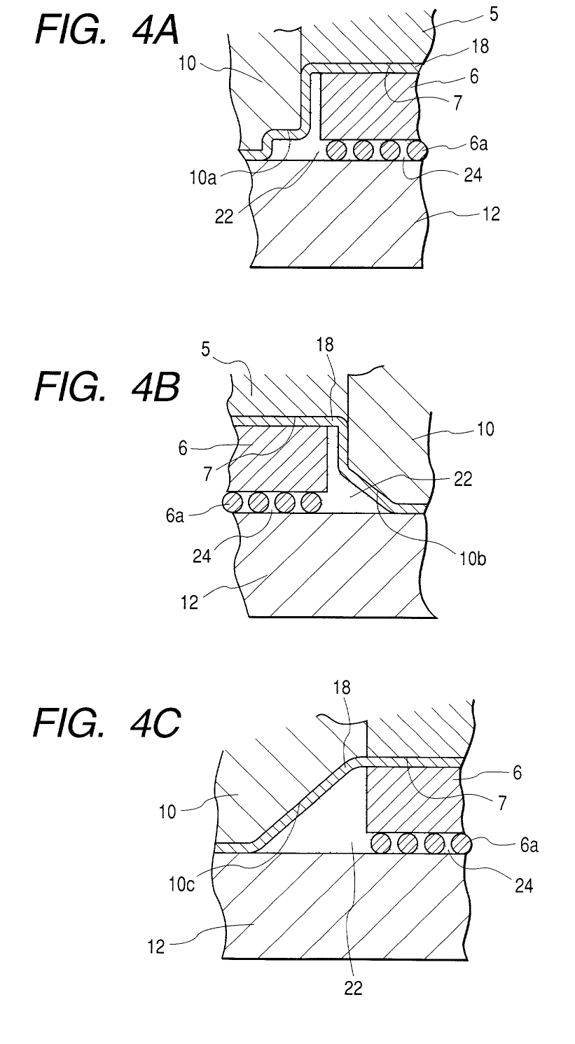

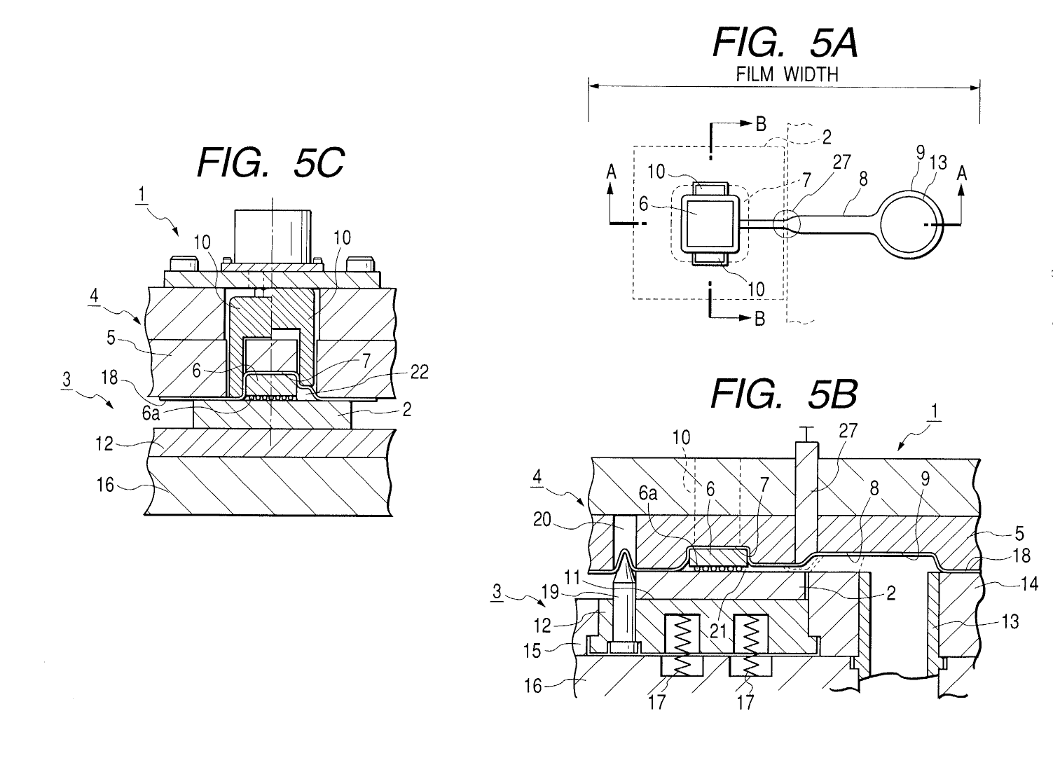

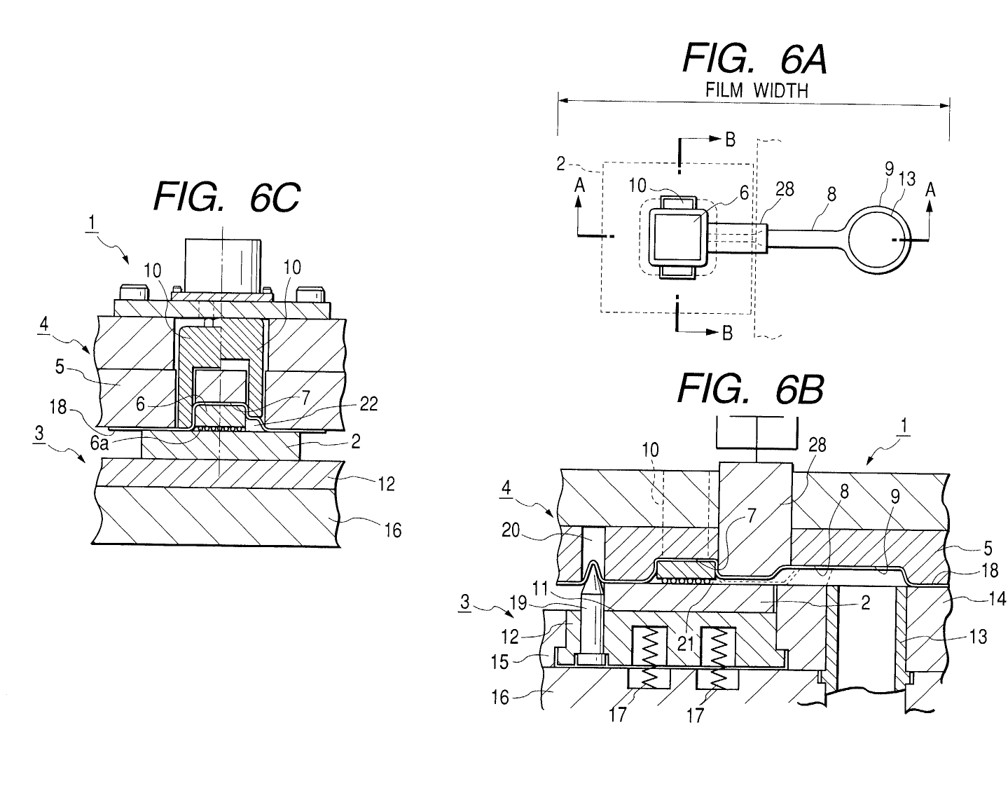

FIGS. 1A, 1B and 1C are, respectively, an exemplary upper view of a metallic molding die of a resin sealing apparatus, a cross-sectional view taken along the arrows A-A, and a cross-sectional view taken along the arrows B-B, which shows states before and after resin is sealed, FIGS. 2A, 2B and 2C are, respectively, a perspective view of a molded component after resin is sealed, a view taken from the above, and a cross-sectional view taken along the arrows C-C, FIGS. 3A to 3E are, respectively, a perspective view of a molded component, after resin is seal, according to another embodiment, an upper view, across-sectional view taken along the arrows C-C, a cross-sectional view taken along the arrows D-D, and an explanatory view of the shape of a semiconductor chip, FIGS. 4A to 4C are explanatory views showing the shape of a movable block, FIGS. 5A, 5B and 5C and FIGS. 6A, 6B and 6C are, respectively, exemplary upper views of a metallic molding die of a resin sealing apparatus showing another example, and cross-sectional views taken along the arrows A-A, and cross-sectional views taken along the arrows B-B, which show states before and after resin is sealed.

First, a description is given of a general construction of the resin sealing apparatus with reference to FIGS. 1A to 1C and FIGS. 2A to 2C.

First, in FIG. 1B, a metallic molding die 1 is provided with a lower mold 3 on which a substrate 2 is placed, and an upper mold 4 in which a resin pass is formed. A cavity recess portion 7 for accommodating a semiconductor chip 6 connected to the substrate 2 in the form of flip chip, a metallic die gate rubber 8 that communicates the corresponding cavity recess portion 7, and a resin pass such as a metallic die cull 9, etc., are formed in the upper mold block 5 of the upper mold 4. The substrate 2 to which a semiconductor chip 6 is connected in the form of flip chip via an electrode terminal 6a such a bump or soldering ball, etc., may be used as a component to be molded. An epoxy based resin substrate, polyimide based resin substrate, BT (Bismaleimide.Triazine) substrate may be used as the substrate in addition to a ceramic substrate. Also, the substrate 2 may be of a single-layered matrix or multi-layered matrix.

In the upper mold 4, a movable block (fillet fork) 10 is provided at both side faces (both sides with respect to the resin-sealing direction into the under-fill portion) of the semiconductor chip 6 so as to protrude into the cavity recess portion 7. The movable block 10 is provided so as to protrude into the cavity recess portion 7 by drive of a cylinder (not illustrated) Also, if the under-fill mold can be preferentially carried out, the movable block 10 may be omitted. In this case, both side faces of the semiconductor chip 6 may be the inner wall face of the cavity recess portion 7.

Also, a substrate incorporating portion 11 on which the substrate 2 is mounted, a lower mold insert block 12 that forms the corresponding substrate incorporating portion 11, a pot 13 internally incorporating a plunger (not illustrated), a pot insert 14 secured at the surrounding of the pot 13, an end block 15 secured at the surrounding of the lower mold insert block 12, and a lower mold base block 16 that supports the above-described pot insert 14, lower mold insert block 12 and end block 15, are provided in the lower mold 3.

The lower mold insert block 12 is pressed upward by a lower mold spring 17 that is resiliently mounted between the block 12 and the lower mold base block 16.

A release film 18 covers the cavity recess portion 7 of the upper mold 4 and a resin pass (metallic die gate runner 8, metallic die cull 9, etc.) that communicates the corresponding cavity recess portion 7, wherein the semiconductor chip 6 and the upper surface of the substrate 2 are exposed to be sealed with resin. The release film 18 is heat-resistant so as to ensure the heating temperature of the metallic molding die 1 and is easily peeled off from the metallic mold surface. A film material having flexibility and an elongating property, for example, PTEE, ETEE, PET, FEP, fluorine-impregnated glass cloth, polypropylene, polychlorovinylidene, etc., may be preferably employed as the release film 18. The release film 18 is adsorbed and retained by sucking air through an adsorption hole (not illustrated) formed on the parting face of the upper mold block 5. The release film 18 may be continuously supplied to the metallic molding die from a release film supply mechanism (not illustrated) using a film roll wound between reels, or may be such that a film is cut to be stripes of sheet.

A protrusion pin 19 is provided in the lower insert block 12 so as to protrude upward, wherein the tip end part protrudes upward from the substrate 2. An insertion hole 20 is provided at the position opposite to the protrusion pin 19 in the upper mold block 5. When clamping the metallic molding die 1, the protrusion pin 19 slightly pushes the release film 18 into the insertion hole 20 to prevent the release film 18 from being wrinkled or slackening.

Also, in FIGS. 1A and 1B, the section of a resin pass at the position that communicates from the substrate end of the die gate runner 8 of the upper mold 4 to the cavity recess portion 7 is formed to be smaller than the section of the resin pass at the position that communicates from the substrate end to the pot 13, whereby stress is easily concentrated at the substrate end of the molded component gate runner to enable that the gate runner is easily broken off at a fixed position.

In addition, the resin sealing apparatus is provided with an already known opening/closing mechanism that opens and close the metallic molding die 1 by vertically moving the lower mold 3 by means of a toggle mechanism using an electric motor, a transfer mechanism by which a sealing resin is sent under pressure from the pot 13 into the cavity through the resin pass.

A description is given of the resin sealing method. A release film 18 is adsorbed and retained on the cavity recess portion 7 in which the semiconductor chip 6 of the upper mold 4 is accommodated, and on the upper mold surface that communicates with the corresponding cavity recess portion 7. And, a substrate 2 to which a semiconductor chip 6 is connected in the form of flip chip is carried in the substrate incorporating portion 11 of the lower mold 3 of the metallic molding die 1, and resin tablets are inputted in the pot. Then, the metallic molding die 1 is clamped by operating the die opening and closing mechanism (not illustrated). Subsequently, the transfer mechanism (not illustrated) is actuated to elevate the plunger, wherein a sealing resin is sent from the pot 13 into the cavity under pressure through the resin pass.

At this time, as shown at the left half side in FIG. 1C, the movable block 10 secured at both side faces of the semiconductor chip 6 is caused in advance to protrude into the cavity recess portion 7 and the release film 18 is pushed and is brought into contact with the surface of the substrate 2, whereby a sealing resin 22 is pressurized and is preferentially sent into the clearance 21 between the semiconductor chip 6 and the substrate 2 to perform under-fill molding. And, as the sealing resin 22 reaches the downstream side from the gate side of the semiconductor chip 6, as shown at the right half side in FIG. 1C, the movable block 10 is retreated upward, wherein resin sealing is carried out. Further, it is recommended that the timing at which the movable block 10 is retreated from the substrate 2 is at least simultaneously with the charging of the sealing resin 22 into the under-fill portion 24 or thereafter, whereby, as shown in FIGS. 2A through 2C, the molded component 23 is molded in a state where a part of the component gate runner 25 connected to the under-fill portion 24 is left over on the substrate 2. Since the component gate runner 25 is formed so that the cross-section of the resin pass is stopped down at the substrate end, stress is liable to be concentrated and the gate runner can be easily broken off at a fixed position. Also, as shown in FIG. 2B, a sealing resin 22 is spread in the surroundings through the respective corner portions 6b of the semiconductor chip 6, wherein a resin ring portion 24a may be formed. In this case, stress concentration that is liable to occur at the corner portions 6b of the semiconductor chip 6 can be relieved. Therefore, there is no fear that the semiconductor chip 6 is damaged. In this case, it is preferable that gold plating is coated on the inner surface of the resin pass on the substrate 2.

Also, in FIGS. 3A through 3C, it is preferable that a V-shaped groove 26 inclined with respect to the substrate end face is formed on the substrate end position of the component gate runner 25 remaining on the substrate 2. The V-shaped groove 26 may be formed by a protrusion, etc., which is provided on the base end position of the resin pass formed on the upper mold block 5 so as to protrude therefrom. In this case, it is possible to securely break the gate runner with slight stress by the V-shaped groove 26 formed at the substrate end position of the component gate runner 25.

In addition, as shown in FIG. 3D, it is preferable that a chambered portion 6c is formed at the respective corner portions 6b of the semiconductor chip 6. Further, as shown in FIG. 3E, a chambered portion 6c may be formed on the entire circumference of the upper edge portion including the respective corner portions 6b. The chamfered portion 6c may be formed by chambering with respect to the semiconductor chip 6, using, for example, a stepped grinding wheel. With the chamfered portion 6c, the release film 18 will be hardly broken, wherein the productivity can be further improved. Still further, since it is possible to prevent the release film 18 from excessive elongation, edge traces resulting from the respective corner portions 6b can be removed when the corresponding film 18 is swelled.

In addition, the shape of the tip end portion of the movable block 10 may be of various modes, for example, a shape in which a step 10a is formed at the tip end portion of the semiconductor chip side as shown in FIG. 4A, a shape in which a tapered portion 10b is formed at the tip end portion at the semiconductor chip side as shown in FIG. 4B, or a shape in which a chamfered portion 10c is formed at the tip end portion at the semiconductor chip side as shown in FIG. 4C.

According to the above-described resin sealing method and resin sealing apparatus, since it is possible to employ the existing resin sealing method and resin sealing apparatus in which only the upper release film of the upper and lower release films used in prior art molding dies 1 is used with no lower release film used, the production cost and running cost thereof can be decreased. Also, since the lower release film may be omitted, a molded component 23 can be taken out by opening the die with the component 23 placed at the lower mold 3 side, wherein the procedure for taking out the component 23 can be simplified. Also, stress is likely to be concentrated by narrowing the sectional area of the component gate runner 25 at the substrate end or forming a V-shaped groove 26, wherein the gate runner of unnecessary resin can be broken off with slight stress and at a fixed position.

Next, a description is given of another example of the resin sealing method and resin sealing apparatus with reference to FIGS. 5A to 5C and FIGS. 6A to 6C. Also, parts that are identical to those of the resin sealing apparatus in FIG. 1 are given the same reference numbers, and description thereof is omitted.

In FIGS. 5A and 5B, the movable gate pin 27 is provided at the substrate end position of the resin pass of the upper mold 4 so as to protrude with respect to the resin pass. The movable gate pin 27 is caused to protrude into the resin pass by drive of a cylinder, etc., (not illustrated) so as to close the resin pass.

The movable gate pin 27 is caused to protrude into the resin pass simultaneously with the retraction of the movable block 10 secured at both side face (both side portion with respect to the direction for sealing resin into the under-fill portion) of the semiconductor chip 6 shown in FIG. 5C after the under-fill molding is completed, or at an appointed timing thereafter, and the resin pass is closed, wherein the movable gate pin 27 pushes a sealing resin 22 at the substrate end position back to the pot 13 side and seals up resin.

According to the above-described resin sealing method and resin sealing apparatus, the thickness of resin of the gate runner 25 at the substrate end of the molded component 23 can be made thinner, wherein the gate runner can be easily broken off.

Also, in FIGS. 6A and 6B, a movable runner block 28 is provided with respect to the resin pass from the substrate end of the upper mold 4 to the clearance portion so as to protrude therefrom. The movable runner block 28 is caused to protrude into the resin pass by drive of a cylinder, etc., (not illustrated) so as to close the resin pass.

The movable runner block 28 is caused to protrude into the resin pass simultaneously with the retraction of the movable block 10 secured at both side face (both side portion with respect to the direction for sealing resin into the under-fill portion) of the semiconductor chip 6 shown in FIG. 6C after the under-fill molding is completed, or at an appointed timing thereafter, and the resin pass is closed, wherein the movable runner block 28 pushes a sealing resin 22 on the substrate back to the pot 13 side and seals up resin.

According to the above-described resin sealing method and resin sealing apparatus, even if the component gate runner 25 on the substrate of the molded component 23 remains, it is very thin. Therefore, the procedure for breaking off the gate will become unnecessary, or the procedure can be made remarkably simple.

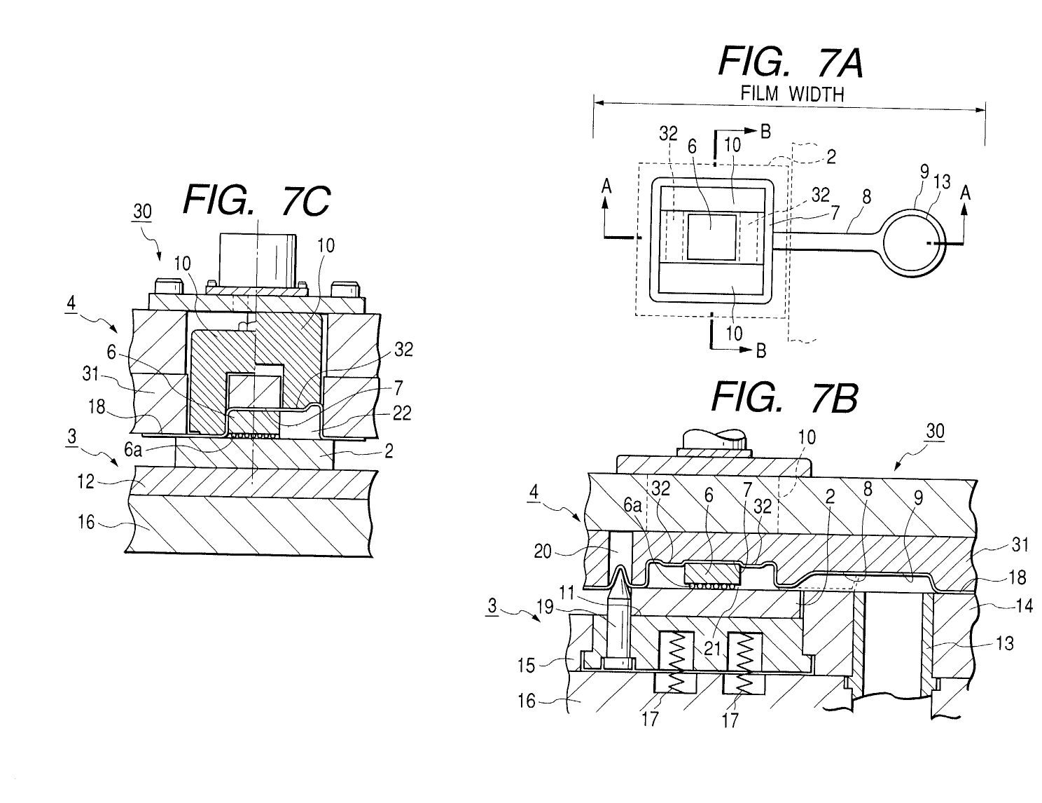

Further, a description is given of still another example of the resin sealing method and resin sealing apparatus with reference to FIGS. 7A to 7C through FIGS. 9A to 9C. Also, parts that are identical to those in the resin sealing apparatus in FIGS. 1A to 1C are given the same reference numbers, wherein overlapping description is omitted.

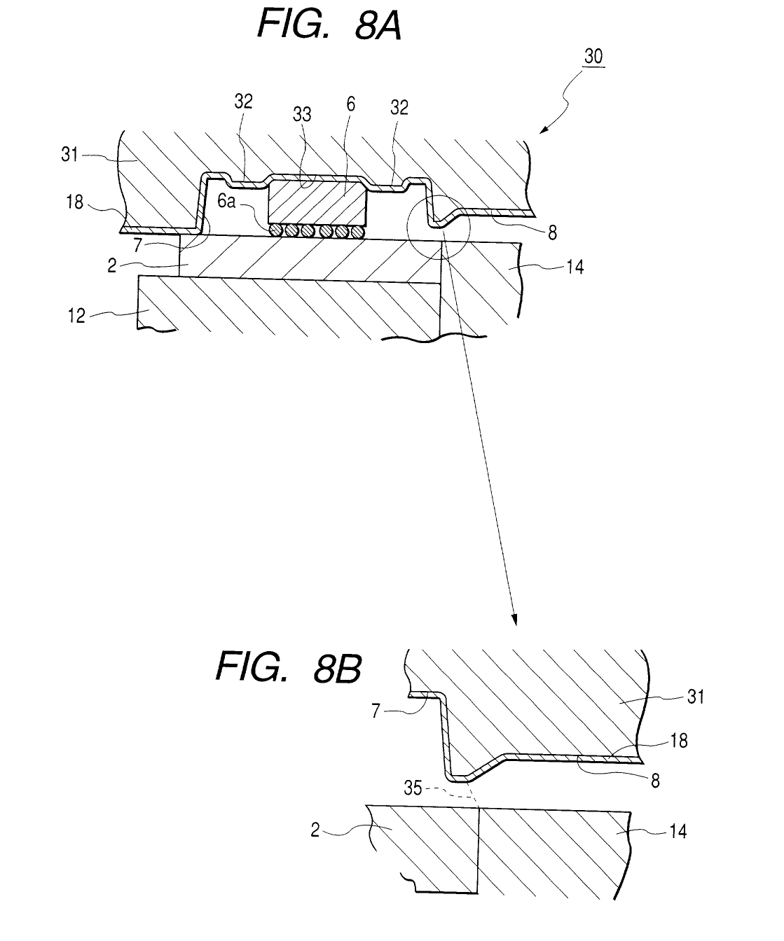

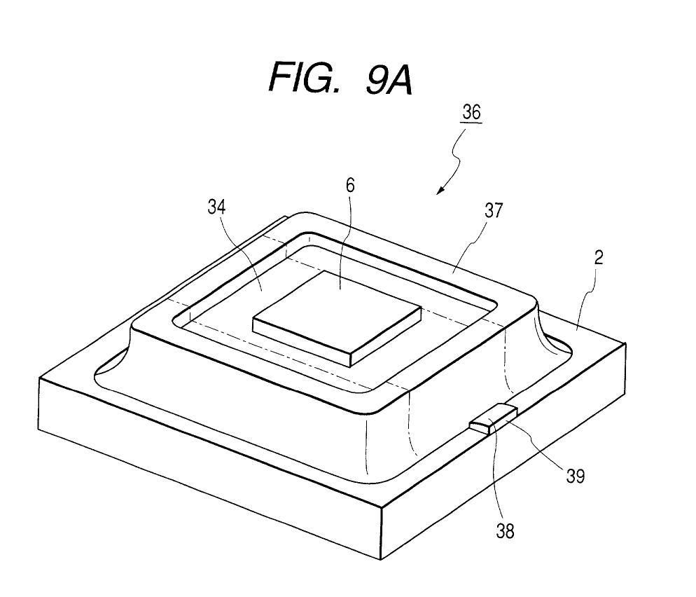

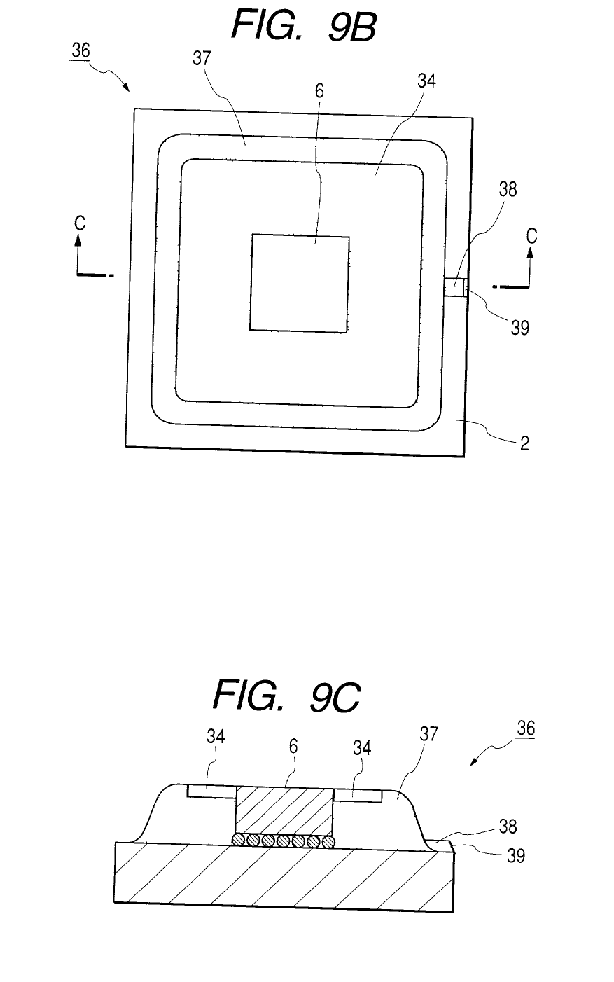

In FIGS. 7A through 7C, a metallic die projection 32 is formed on the cavity recess portion 7 of an upper mold block 31 of the metallic molding die 30. The metallic die projection 32 seals up resin by forming a recess 34 of the molded component at a resin sealing portion 37 around the corresponding semiconductor chip 6 when sealing the semiconductor chip 6 with resin (Refer to FIGS. 9A through 9C). After resin is sealed, a heat radiation plate (not illustrated) is adhered onto the upper surface of the semiconductor chip 6. At this time, an adhesive agent is coated in the recess 34 of the molded component formed on the resin sealing portion 37, with which the heat radiation plate is adhered. FIGS. 8A and 8B show a construction of the metallic molding die 30. In the case of the present embodiment, as shown in FIG. 8A, a metallic die recess 33 that clamps the semiconductor chip 6 is provided in the cavity recess portion 7 of the upper mold 32, and a metallic die projection 32 is provided at the surrounding thereof. In this case, it is enough that the recess and projection have been designed so that the exposed portion of the semiconductor chip 6 after resin is sealed becomes higher by, for example, 0.05 mm than the recess portion 34 of the molded component. Also, the metallic die gate runner 8 is formed on the upper mold 32 so that it is connected to the substrate end, and the degating line 35 of the corresponding metallic die gate runner 8 has been designed so as not to protrude the substrate end portion as shown with a broken line in a partially enlarged view of FIG. 8B.

FIGS. 9A through 9C show a molded component 36 that is sealed with resin by using a metallic molding die shown in FIGS. 7A to 7C. In FIGS. 9A through 9C, a tapered portion 39 that is inclined with respect to the substrate end face is formed in the molded component gate 38 due to breakage of the gate runner along the degating line shown in FIG. 8B.

Thus, since a heat radiation plate (not illustrated) is adhered onto the upper surface of the semiconductor chip 6, the thickness of the adhesive agent layer by which the heat radiation plate is adhered can be absorbed by the resin sealing portion 37 by forming a recess 34 of a molded component in the resin sealing portion 37 that seals up the surrounding of the semiconductor chip. Therefore, the height of a package can be suppressed to be low.

Some of preferred embodiments of the present invention have been described. However, the resin sealing method and resin sealing apparatus according to the invention are not limited to the above examples. For example, the thickness of resin of the gate runner of a molded component, which is formed on a substrate, can be freely designed, and the timing at which a movable block protruding into the cavity recess portion is retreated after under-fill molding is completed is also optional. That is, the invention can be subjected to various modifications and variations without departing from the spirit of the invention.

With the resin sealing method and resin sealing apparatus according to the invention, since it is possible to employ the existing resin sealing method and resin sealing apparatus in which only the upper film of the upper and lower release films used in prior art molding dies of a resin sealing apparatus is used with no lower release film used, the production cost and running cost thereof can be decreased. Also, since the lower release film may be omitted, a molded component can be taken out by opening the die with the component placed at the lower mold side, wherein the procedure for taking out the component can be simplified. Also, stress is likely to be concentrated on the substrate end by narrowing the sectional area of the component gate runner at the substrate end or forming a V-shaped groove, wherein the gate runner of unnecessary resin can be broken off with slight stress and at a fixed position.

Also, where a movable gate pin is provided at the substrate end position of the upper mold so as to protrude into the resin pass, and a movable rubber block is provided so as to protrude into the resin pass that communicates from the substrate end with the cavity recess portion, since a sealing resin on the substrate is pushed back to the pot side for resin sealing by closing the resin pass by the movable gate pin or movable runner block after under-fill molding is completed, the thickness of the resin of the component gate runner on the substrate can be made thin, or thinly coated, wherein the gate breakage will be made remarkably easy or can be omitted.

Further, where a chamfered portion is formed at the upper edge portion including at least respective corner portions of the semiconductor chip, the release film will be hardly broken, and the productivity can be further improved, and it is possible to prevent the release film from being excessively elongated. Therefore, edge traces that occur due to the respective corners when the release film is swelled can be eliminated.

Also, where a recess portion is formed at the resin sealing portion that seals up the surrounding of the semiconductor chip in order to adhere a heat radiation plate to the corresponding semiconductor chip, since the thickness of the adhesive agent layer that adheres the heat radiation plate can be absorbed by the resin sealing portion, it is possible to suppress the height of a package to a low level.

What is claimed is:

1. A resin sealing method for sealing a semiconductor chip flip-chip bonded with a substrate, the method comprising:
covering with a release film a face of an upper mold including a cavity recess portion and a resin pass communicating with the cavity recess portion;
putting the semiconductor chip with the substrate in the cavity recess portion;
clamping the semiconductor chip with the substrate by the upper mold and the lower mold;
delivering under pressure a sealing resin to a clearance between the semiconductor chip and the substrate with priority to perform under-fill molding and to form a molded component; and
separating a component gate runner connected to the under-fill portion, at the end of the substrate.

2. The resin sealing method as set forth in claim 1, further comprising:
protruding a movable block secured in the upper mold, into the cavity recess portion at both side faces of the semiconductor chip to push the release film to the semiconductor chip before performing the under-fill molding;
retreating the movable block; and
sealing both the side faces of the semiconductor chip with resin.

3. The resin sealing method as set forth in claim 1, wherein resin is sealed so that the resin molding thickness of a portion that communicates from the substrate end of a molded component gate runner to the under-fill portion is made thinner at the pot side than that at the substrate end.

4. The resin sealing method as set forth in claim 1, wherein resin is sealed so that a V-shaped groove is formed at the substrate end position of a molded component gate runner remaining on the substrate.

5. The resin sealing method as set forth in claim 1, wherein a movable gate pin is provided at the substrate end position of the upper mold so as to protrude with respect a resin pass, and by closing the resin pass by the movable gate pin after the under-fill molding is completed, resin is sealed by pushing a sealing resin at the substrate end position back to the pot side.

6. The resin sealing method as set forth in claim 1, wherein a movable runner block is provided in the upper mold so as to protrude from the substrate end to the resin pass that communicates with the cavity recess portion, and by closing the resin pass by the movable runner block after the under-fill molding is completed, resin is sealed by pushing the sealing resin on the substrate back to the pot side.

7. A resin sealing apparatus for sealing a clearance between a semiconductor chip and a substrate flip-chip bonded to the semiconductor chip with resin, the apparatus comprising:
a lower mold on which a semiconductor chip with the substrate is placed, an upper mold defining a cavity recess portion for accommodating the semiconductor chip with the substrate and a resin pass communicating with the cavity recess portion; and
a release film that covers the cavity recess portion and the resin pass;
wherein a sealing resin is delivered under pressure to the clearance between the semiconductor chip and substrate with priority to perform under-fill molding; and
the semiconductor chip is sealed with resin, with a molded component gate runner to be connected to the under-fill portion remaining on the substrate.

8. The resin sealing apparatus as set forth in claim 7, further comprising a movable block at both side faces of the semiconductor chip, the movable block provided in the upper mold to protrude into the cavity recess portion,
wherein the movable block is caused to protrude in advance into the cavity recess portion, under-fill molding is performed with the release film pushed to the substrate, and both side faces of the semiconductor chip are sealed with resin after retreating the movable block.

9. The resin sealing apparatus as set forth in claim 7, wherein the cross section of a resin pass at a portion that communicates from the substrate end of the metallic mold gate runner formed on the upper mold to the cavity recess portion is formed to be smaller than the cross section of the resin pass at a portion that communicates from the substrate end to a pot.

10. The resin sealing apparatus as set forth in claim 7, wherein the semiconductor chip is chamfered at the upper edge portion including at least respective corners.

11. The resin sealing apparatus as set forth in claim 7, further comprising a movable gate pin provided at the substrate end position of the upper mold to protrude with respect to the resin pass,
wherein the semiconductor chip is sealed with resin by pushing the sealing resin at the substrate end position back to the pot side by closing the resin pass by the movable gate pin after the under-fill molding is completed.

12. The resin sealing apparatus as set forth in claim 7, further comprising a movable runner block provided in the upper mold to protrude from the substrate end to the resin pass that communicates with the cavity recess portion,
wherein, by closing the resin pass by the movable runner block after the under-fill molding is completed, resin is sealed by pushing the sealing resin on the substrate back to the pot side.
